(19) United States
(12) Patent Application Publication
(10) Pub. No.: US 2019/0033438 A1
(43) Pub. Date: Jan. 31, 2019

(54) DISTANCE DETECTION DEVICE AND DISTANCE DETECTION METHOD THEREOF

(71) Applicant: Acer Incorporated, New Taipei City (TW)

(72) Inventors: Po-Jen Tu, New Taipei City (TW); Jia-Ren Chang, New Taipei City (TW); Kai-Meng Tzeng, New Taipei City (TW)

(73) Assignee: Acer Incorporated, New Taipei City (TW)

(21) Appl. No.: 15/823,584

(22) Filed: Nov. 28, 2017

(30) Foreign Application Priority Data
Jul. 27, 2017 (TW) 106125347
Jul. 28, 2017 (TW) 106125492

(51) Int. Cl. G01S 11/16; G01S 5/30; G01R 23/165; G01R 23/16

(52) U.S. Cl. CPC G01S 11/16; G01R 23/16; G01R 23/165; G01S 5/30

(57) ABSTRACT

A distance detection device and a distance detection method thereof are provided. A second time at which a packet amplitude peak of a preset sound signal is received by a sound receiver is estimated according to a time difference between the preset sound signal and a low pass filter signal thereof. A distance between a speaker and the sound receiver is calculated according to the second time.

### CROSS-REFERENCE TO RELATED APPLICATION

This application claims the priority benefit of Taiwan application serial no. 106125347, filed on Jul. 27, 2017, and Taiwan application serial no. 106125492, filed on Jul. 28, 2017. The entirety of each of the above-mentioned patent applications is hereby incorporated by reference herein and made a part of this specification.

### BACKGROUND OF THE INVENTION

### 1. Field of the Invention

The invention relates to a detection device, and more particularly, to a distance detection device and a distance detection method thereof.

### 2. Description of Related Art

In general, when calculating a relative distance between a signal source and a receiver, a time difference between a signal outputted by the signal source and a signal received by the receiver may be obtained by calculating for a cross-correlation on the received signal and the original output signal at each time point. Because a time corresponding to a maximum value of a cross-correlation signal is a time when the signal is received and a time when the signal is outputted is known, the relative distance may be calculated according to a difference between the time when the signal is received and the time when the signal is outputted. Although the relative distance may be effectively calculated this way, the frequent execution of cross-correlation operations will consume a considerable amount of resources. In addition, when a relative velocity between the receiver and the signal source is not equal to zero, it is unable to accurately calculate the relative distance between the receiver and the signal source.

### SUMMARY OF THE INVENTION

The invention is directed to a distance detection device and a distance detection method thereof, which are capable of significantly saving computational resources and accurately detecting a relative distance between an output signal source and a signal receiver.

A distance detection device of the invention includes a speaker, a sound receiver and a processor. The speaker outputs a preset sound signal. The preset sound signal has an amplitude and a frequency that vary over time. A time difference exists between the preset sound signal and a first low pass filter signal obtained after performing a low pass filtering on the preset sound signal. A packet amplitude peak of the preset sound signal is outputted by the speaker at a first time. The processor performs the low pass filtering on a sound signal received by the sound receiver to generate a second low pass filter signal. The processor estimates a second time corresponding to when the packet amplitude peak of the preset sound signal is received by the sound receiver according to the time difference and the second low pass filter signal. The processor calculates a distance between the speaker and the sound receiver according to the second time.

In an embodiment of the invention, the processor further determines whether a relative velocity between the speaker and the sound receiver is zero. When the relative velocity between the speaker and the sound receiver is zero and a difference between a frequency value of the sound signal received by the sound receiver corresponding to the second time and a frequency value of the preset sound signal outputted by the speaker corresponding to the first time does not exceed a preset range, the processor performs a cross-correlation operation on the preset sound signal outputted by the speaker within a first time length based on the first time and the sound signal received by the sound receiver within a second time length based on the second time so as to generate a cross-correlation signal, and calculates the distance between the speaker and the sound receiver according to a time corresponding to a packet amplitude peak of the cross-correlation signal and the first time. The second time length is greater than the first time length.

In an embodiment of the invention, the processor performs a Fourier transform operation on the sound signal received by the sound receiver within the first time length based on the second time and determines whether a difference between a frequency value of the sound signal received by the sound receiver having a maximum amplitude in a frequency domain within the first time length based on the second time and the frequency value of the preset sound signal outputted by the speaker corresponding to the first time exceeds the preset range. When the preset range is not exceeded, the processor performs the cross-correlation operation on the preset sound signal outputted by the speaker within the first time length based on the first time and the sound signal received by the sound receiver within the second time length based on the second time.

In an embodiment of the invention, the time difference is a difference between the first time and a third time corresponding to a packet amplitude peak of the first low pass filter signal.

In an embodiment of the invention, the speaker and the sound receiver are disposed in a space, and the second time length is less than a time required to transmit the preset sound signal for a farthest relative distance possibly disposed between the speaker and the sound receiver within the space.

In an embodiment of the invention, the preset sound signal has a third time length, and the second time length is greater than or equal to the third time length.

In an embodiment of the invention, the first time length is a time length during which a packet amplitude of the preset sound signal is less than a preset value.

In an embodiment of the invention, the low pass filtering is an infinite impulse response filtering.

In an embodiment of the invention, the cross-correlation operation is a fast cross-correlation operation.

In an embodiment of the invention, the speaker outputs the preset sound signal in an m^{th} time period where m is an integer greater than 1. The preset sound signal has a first frequency at the first time. The processor further determines whether a relative velocity between the speaker and the sound receiver is zero. When the relative velocity between the speaker and the sound receiver is not zero, the processor corrects a frequency value of the preset sound signal by using a Doppler effect according to the relative velocity between the speaker and the sound receiver previously calculated, performs a cross-correlation operation on the corrected preset sound signal and the sound signal received by the sound receiver so as to generate a cross-correlation signal, and calculates the distance between the speaker and the sound receiver according to a time corresponding to a packet amplitude peak of the cross-correlations signal and the first time so as to obtain a corrected relative distance. The sound signal received by the sound receiver at the second time corresponds to a second frequency.

In an embodiment of the invention, the processor calculates the relative velocity between the speaker and the sound receiver corresponding to the m^{th} time period according to the corrected relative distance between the speaker and the sound receiver corresponding to the m^{th} time period and the corrected relative distance between the speaker and the sound receiver corresponding to an (m-1)^{th} time period, and determines whether the relative velocity between the speaker and the sound receiver corresponding to the m^{th} time period is converged to fall within a preset range according to the relative velocity between the speaker and the sound receiver corresponding to the mth time period and the relative velocity between the speaker and the sound receiver corresponding to the (m-1)^{th} time period.

In an embodiment of the invention, the relative distance between the speaker and the sound receiver corresponding to the m^{th} time period is used as a final confirmed relative distance when a difference between the relative velocity between the speaker and the sound receiver corresponding to the m^{th} time period and the relative velocity between the speaker and the sound receiver corresponding to the (m-1)^{th} time period divided by the relative velocity between the speaker and the sound receiver corresponding to the m^{th} time period does not exceed the preset range.

In an embodiment of the invention, the processor calculates an initial relative velocity between the speaker and the sound receiver by using the Doppler effect according to the first frequency and the second frequency.

In an embodiment of the invention, the processor performs a Fourier transform operation on the sound signal received by the sound receiver within a time length centered on the second time so as to obtain the second frequency.

In an embodiment of the invention, the processor further performs an interpolation operation on a plurality of frequency domain signals obtained after the Fourier transform operation is performed so as to obtain the second frequency.

In an embodiment of the invention, the time difference is a difference between the first time and a third time corresponding to a packet amplitude peak of the first low pass filter signal.

In an embodiment of the invention, the speaker and the sound receiver are disposed within a space, and a time length of each time period for outputting the preset sound signal is equal to a time length required to transmit the preset sound signal for a farthest relative distance possibly disposed between the speaker and the sound receiver within the space.

In an embodiment of the invention, the low pass filtering is an infinite impulse response filtering.

In an embodiment of the invention, the cross-correlation operation is a fast cross-correlation operation.

The invention also provides a distance detection method of a distance detection device. The distance detection device includes a speaker and a sound receiver. The speaker outputs a preset sound signal. The preset sound signal has an amplitude and a frequency that vary over time. A time difference exists between the preset sound signal and a first low pass filter signal obtained after performing a low pass filtering on the preset sound signal. A packet amplitude peak of the preset sound signal is outputted by the speaker at a first time. The distance detection method of the distance detection device includes the following steps. The low pass filtering is performed on a sound signal received by the sound receiver to generate a second low pass filter signal. A second time corresponding to when the packet amplitude peak of the preset sound signal is received by the sound receiver is estimated according to the time difference and the second low pass filter signal. A distance between a speaker and the sound receiver is calculated according to the second time.

In an embodiment of the invention, the distance detection method of the distance detection device includes the following steps. Whether a relative velocity between the speaker and the sound receiver is zero is determined. When the relative velocity between the speaker and the sound receiver is zero, whether a difference between a frequency value of the sound signal received by the sound receiver corresponding to the second time and a frequency value of the preset sound signal outputted by the speaker corresponding to the first time exceeds a preset range is determined. If the difference between the frequency value of the sound signal received by the sound receiver corresponding to the second time and the frequency value of the preset sound signal outputted by the speaker corresponding to the first time does not exceed the preset range, a cross-correlation operation is performed on the preset sound signal outputted by the speaker within a first time length based on the first time and the sound signal received by the sound receiver within a second time length based on the second time so as to generate a cross-correlation signal. The second time length is greater than the first time length. The distance between the speaker and the sound receiver is calculated according to a time corresponding to a packet amplitude peak of the cross-correlation signal and the first time.

In an embodiment of the invention, the distance detection method of the distance detection device includes the following steps. A Fourier transform operation is performed on the sound signal received by the sound receiver within the first time length based on the second time. Whether a difference between a frequency value of the sound signal received by the sound receiver having a maximum amplitude in a frequency domain within the first time length based on the second time and the frequency value of the preset sound signal outputted by the speaker corresponding to the first time exceeds the preset range is determined. If the preset range is not exceeded, the cross-correlation operation is performed on the preset sound signal outputted by the speaker within the first time length based on the first time and the sound signal received by the sound receiver within the second time length based on the second time.

In an embodiment of the invention, the time difference is a difference between the first time and a third time corresponding to a packet amplitude peak of the first low pass filter signal.

In an embodiment of the invention, the speaker and the sound receiver are disposed in a space, and the second time length is less than a time required to transmit the preset sound signal for a farthest relative distance possibly disposed between the speaker and the sound receiver within the space.

In an embodiment of the invention, the preset sound signal has a third time length, and the second time length is greater than or equal to the third time length.

In an embodiment of the invention, the first time length is a time length during which a packet amplitude of the preset sound signal is less than a preset value.

In an embodiment of the invention, the low pass filtering is an infinite impulse response filtering.

In an embodiment of the invention, the cross-correlation operation is a fast cross-correlation operation.

In an embodiment of the invention, the speaker outputs the preset sound signal in an m^{th} time period where in is an integer greater than 1. The preset sound signal outputted by the speaker has a first frequency at the first time. The distance detection method of the distance detection device includes the following steps. Whether a relative velocity between the speaker and the sound receiver is zero is determined. When the relative velocity between the speaker and the sound receiver is not zero, a second time corresponding to when the packet amplitude peak of the preset sound signal is received by the sound receiver is estimated according to the time difference and the second low pass filter signal. The sound signal received by the sound receiver at the second time corresponds to a second frequency. A frequency value of the preset sound signal is corrected by using a Doppler effect according to the relative velocity between the speaker and the sound receiver previously calculated. A cross-correlation operation is performed on the corrected preset sound signal and the sound signal received by the sound receiver so as to generate a cross-correlation signal. The distance between the speaker and the sound receiver is calculated according to a time corresponding to a packet amplitude peak of the cross-correlations signal and the first time so as to obtain a corrected relative distance.

In an embodiment of the invention, the distance detection method of the distance detection device includes the following steps. The relative velocity between the speaker and the sound receiver corresponding to the m^{th} time period is calculated according to the corrected relative distance between the speaker and the sound receiver corresponding to the m^{th} time period and the corrected relative distance between the speaker and the sound receiver corresponding to an (m-1)^{th} time period. Whether the relative velocity between the speaker and the sound receiver corresponding to the m^{th} time period is converged to fall within a preset range is determined according to the relative velocity between the speaker and the sound receiver corresponding to the m^{th} time period and the relative velocity between the speaker and the sound receiver corresponding to the (m-1)^{th} time period.

In an embodiment of the invention, the relative distance between the speaker and the sound receiver corresponding to the re time period is used as a final confirmed relative distance when a difference between the relative velocity between the speaker and the sound receiver corresponding to the m^{th} time period and the relative velocity between the speaker and the sound receiver corresponding to the (m-1)^{th} time period divided by the relative velocity between the speaker and the sound receiver corresponding to the m^{th} time period does not exceed the preset range.

In an embodiment of the invention, the distance detection method of the distance detection device includes: calculating an initial relative velocity between the speaker and the sound receiver by using the Doppler effect according to the first frequency and the second frequency.

In an embodiment of the invention, the distance detection method of the distance detection device includes: performing a Fourier transform operation on the sound signal received by the sound receiver within a time length centered on the second time so as to obtain the second frequency.

In an embodiment of the invention, the distance detection method of the distance detection device includes: performing an interpolation operation on a plurality of frequency domain signals obtained after the Fourier transform operation is performed so as to obtain the second frequency.

In an embodiment of the invention, the time difference is a difference between the first time and a third time corresponding to a packet amplitude peak of the first low pass filter signal.

In an embodiment of the invention, the speaker and the sound receiver are disposed within a space, and a time length of each time period for outputting the preset sound signal is equal to a time length required to transmit the preset sound signal for a farthest relative distance possibly disposed between the speaker and the sound receiver within the space.

In an embodiment of the invention, the low pass filtering is an infinite impulse response filtering.

In an embodiment of the invention, the cross-correlation operation is a fast cross-correlation operation.

Based on the above, in the embodiments of the invention, the second time when the packet amplitude peak of the preset sound signal is received by the sound receiver is estimated according to the time difference between the preset sound signal and the low pass filter signal thereof and the low pass filter signal of the sound signal received by the sound receiver, and the distance between the speaker and the sound receiver is calculated according to the second time, such that the relative distance between the speaker and the sound receiver may be accurately calculated while significantly and effectively saving computational resources.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a distance detection device according to an embodiment of the invention.

FIG. 2A is a waveform diagram of a preset sound signal outputted by a speaker according to an embodiment of the invention.

FIG. 2B is a waveform diagram of a sound signal received by a sound receiver according to an embodiment of the invention.

FIG. 3 is a flowchart of a distance detection method of a distance detection device according to an embodiment of the invention.

FIG. 4 is a flowchart of a distance detection method of a distance detection device according to another embodiment of the invention.

FIG. 5 is a flowchart of a distance detection method of a distance detection device according to another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

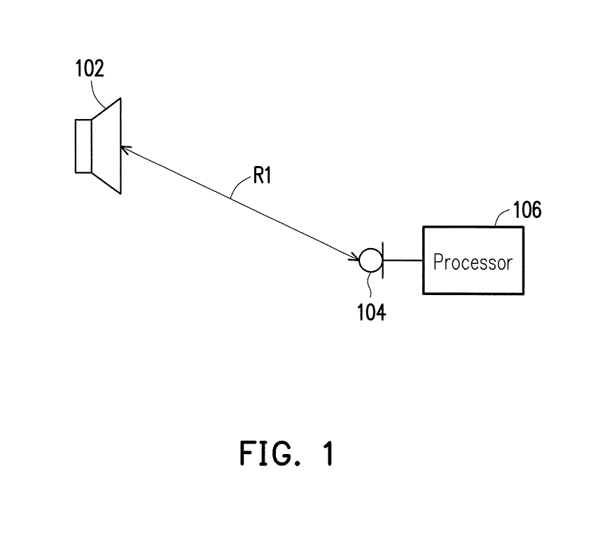

With reference to FIG. 1, FIG. 1 is a schematic diagram of a distance detection device according to an embodiment of the invention. The distance detection device includes a speaker 102, a sound receiver 104 and a processor 106. The processor 106 is coupled to the sound receiver 104, and a distance R1 between the speaker 102 and the sound receiver 104 may be fixed, for example. However, the invention is not limited thereto. The speaker 102 is configured to output a preset sound signal, and the preset sound signal has an amplitude and a frequency that vary over time. In other words, the preset sound signal can correspond to different amplitudes and different frequencies at different time points. The sound receiver 104 is configured to receive a sound signal, and the processor 106 may be configured to perform a signal processing on the preset sound signal and the sound signal received by the sound receiver 104. The processor 106 may be, for example, a central processing unit or other programmable devices for general purpose or special purpose, such as a microprocessor and a digital signal processor (DSP), a programmable controller, an application specific integrated circuit (ASIC), a programmable logic device (PLD) or other similar devices or a combination of above-mentioned devices. Further, the processor 106 may be disposed with a volatility storage medium, such as a random access memory (RAM) or a read only memory (ROM). The processor 106 may be, for example, integrated together with the sound receiver 104 in the same electronic device (e.g., a portable electronic device), or the processor 106 and the sound receiver 104 may be respectively disposed in different electronic devices. In some embodiments, the processor 106 may also conduct a signal transmission with the speaker 102 and the sound receiver 104 through networks or other methods in wired or wireless manner.

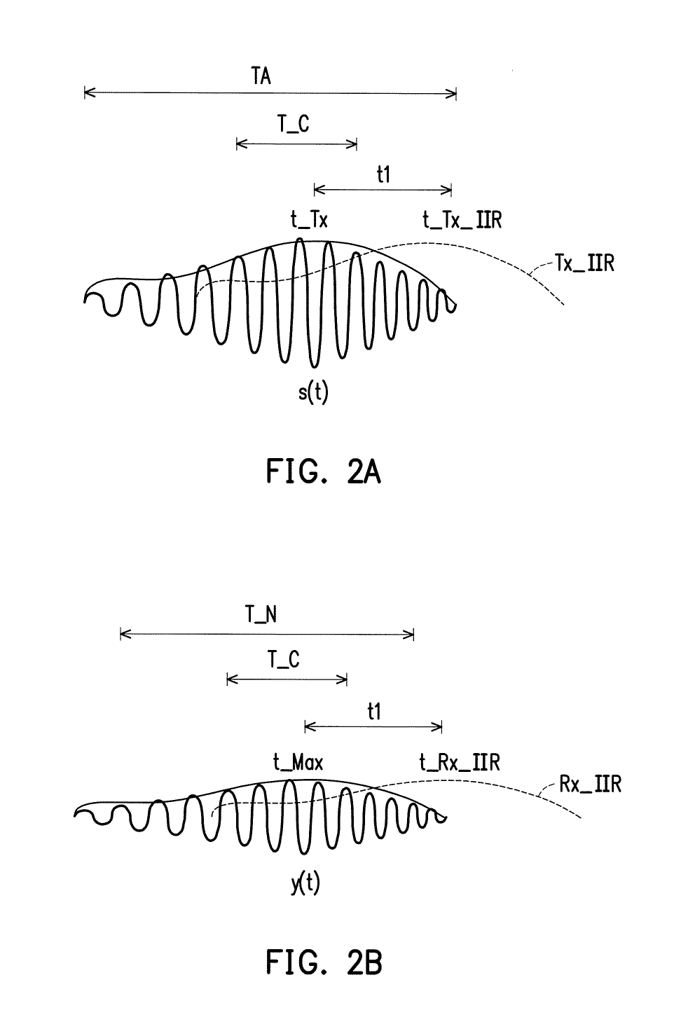

Furthermore, the processor 106 can conduct the signal transmission with the speaker 102 by, for example, a network transmission, so as to obtain a time point at which the preset sound signal is outputted by the speaker 102. A time difference exists between the preset sound signal and a first low pass filter signal obtained by performing a low pass filtering on the preset sound signal (e.g., performing an infinite impulse response filtering on the preset sound signal, but not limited thereto). For instance, FIG. 2A is a waveform diagram of a preset sound signal outputted by a speaker according to an embodiment of the invention. In FIG. 2A, a packet amplitude peak of a preset sound signal s(t) corresponds to a time t_Tx, and a packet amplitude peak of a first low pass filter signal Tx_IIR (as shown by the dotted line) obtained after performing the low pass filtering on the preset sound signal s(t) corresponds to a time t_Tx_IIR. Accordingly, a time difference t1 between the first low pass filter signal Tx_IIR and the preset sound signal s(t) is equal to t_Tx_IIR-t_Tx.

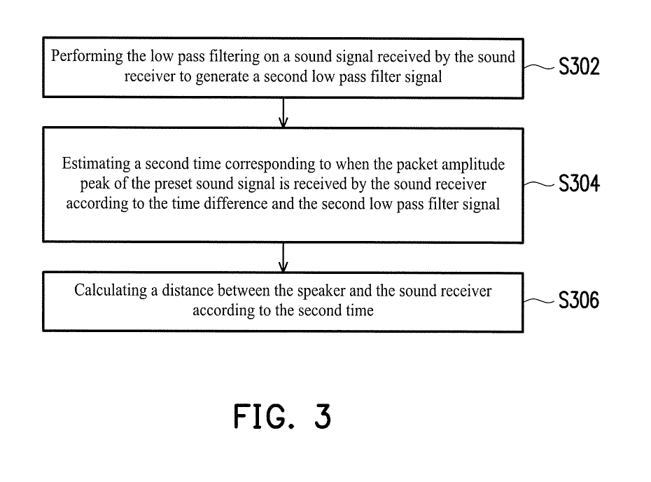

FIG. 3 is a flowchart of a distance detection method of a distance detection device according to an embodiment of the invention. As shown in FIG. 3, the processor 106 can perform the low pass filtering on the sound signal received by the sound receiver 104 (e.g., performing a low pass filtering with the same processing of the low pass filtering performed on the preset sound signal) to generate a second low pass filter signal (step S302). The processor 106 estimates a second time corresponding to when the packet amplitude peak of the preset sound signal is received by the sound receiver 104 according to the time difference and the second low pass filter signal (step S304). For instance, FIG. 2B is a waveform diagram of a sound signal received by a sound receiver according to an embodiment of the invention. In FIG. 2B, a packet amplitude peak of a second low pass filter signal Rx_IIR (as shown by the dotted line) obtained after performing the low pass filtering on a sound signal y(t) received by the sound receiver 104 corresponds to a time t_Rx_IIR. The processor 106 can subtract the time difference t1 from the time t_Rx_IIR so as to estimate a time t_Max corresponding to when the packet amplitude peak of the preset sound signal is received by the sound receiver 104. Then, the processor 106 can calculate a distance between the speaker and the sound receiver according to the second time (step S306).

Furthermore, the processor 106 can determine whether a difference between a frequency value of the sound signal y(t) received by the sound receiver 104 corresponding to the time t_Max and a frequency value of the preset sound signal s(t) outputted by the speaker 102 corresponding to the time t_Tx exceeds a preset range. Specifically, the processor 106 can perform a Fourier transform operation on the sound signal y(t) received by the sound receiver 104 within a time length T_C based on the time t_Max (e.g., centered on the time t_Max, but not limited thereto), and determine whether a difference between a frequency value of a frequency domain signal having a maximum amplitude in a frequency domain of the sound signal y(t) received by the sound receiver 104 within the time length T_C based on the time t_Tx (e.g., centered on the time t_Tx, but not limited thereto) and the frequency value of the preset sound signal s(t) outputted by the speaker 102 corresponding to the time t_Tx exceeds the preset range. When the difference between the frequency value of the sound signal y(t) received by the sound receiver 104 corresponding to the time t_Max and the frequency value of the preset sound signal s(t) outputted by the speaker 102 corresponding to the time t_Tx does not exceed the preset range, it means that the preset sound signal s(t) is received by the sound receiver 104. The time length T_C may be, for example, set as a time length during which a packet amplitude of the preset sound signal s(t) is less than a preset value. In other words, only a portion of the preset sound signal s(t) with the packet amplitude being larger is used for comparing the frequency values so an accuracy of the comparison result may be improved. Moreover, an amount of operations may also be reduced for the processor 106.

When the difference between the frequency value of the sound signal y(t) received by the sound receiver 104 corresponding to the time t_Max and the frequency value of the preset sound signal s(t) outputted by the speaker 102 corresponding to the time t_Tx does not exceed the preset range, the processor 106 can perform a cross-correlation operation on the preset sound signal s(t) outputted by the speaker 102 within the time length T_C based on the time t_Tx and the sound signal received by the sound receiver 104 within a time length T_N based on the time t_Max so as to generate a cross-correlation signal, The cross-correlation operation may be, for example, a fast cross-correlation operation, but not limited thereto. In addition, the time length T_N is greater than the time length T_C. The time length T_N may be, for example, set to be greater than or equal to a time length TA of the preset sound signal s(t) but less than a time required to transmit the preset sound signal s(t) for a farthest relative distance possibly disposed between the speaker 102 and the sound receiver 104 within a space. The processor 106 can calculate the distance R1 between the speaker 102 and the sound receiver 104 according to a time t_Rx corresponding to a packet amplitude peak of the cross-correlation signal (i.e., an accurate time when the packet amplitude peak of the preset sound signal s(t) is received by the sound receiver 104) and the time t_Tx. For instance, the distance R1 between the speaker 102 and the sound receiver 104 may be equal to (t_Rx-t_Tx)c where c is an acoustical velocity.

It should be noted that, in some embodiments, the time length T_N may also be set to be less than the time length TA. For example, the time length T_N may be set as a time length during which the packet amplitude of the preset sound signal s(t) is less than another preset value. By setting the time length T_N to be less than the time required to transmit the preset sound signal s(t) for the farthest relative distance possibly disposed between the speaker 102 and the sound receiver 104 within the space, the processor 106 does not need to perform the cross-correlation operation on the preset sound signal s(t) and the sound signal y(t) received by the sound receiver 104 over a long period of time (at least the time length TA plus the time required to transmit the preset sound signal s(t) for the farthest relative distance possibly disposed between the speaker 102 and the sound receiver 104 within the space) as required in the prior art.

In this way, the time required for the processor 106 to perform the cross-correlation operation on the preset sound signal s(t) and the sound signal y(t) may be significantly reduced. Also, it is given that the processor 106 already determines that the difference between the frequency value of the frequency domain signal having the maximum amplitude in the frequency domain of the sound signal y(t) received by the sound receiver 104 within the time length T_C based on the time t_Tx and the frequency value of the preset sound signal s(t) outputted by the speaker 102 corresponding to the time t_Tx does not exceed the preset range. Therefore, since it can be ensured that the preset sound signal s(t) is indeed received by the sound receiver 104, the time t_Rx when the packet amplitude peak of the preset sound signal s(t) is received by the sound receiver 104 may be obtained accurately, such that the distance R1 between the speaker 102 and the sound receiver 104 may then be calculated accordingly.

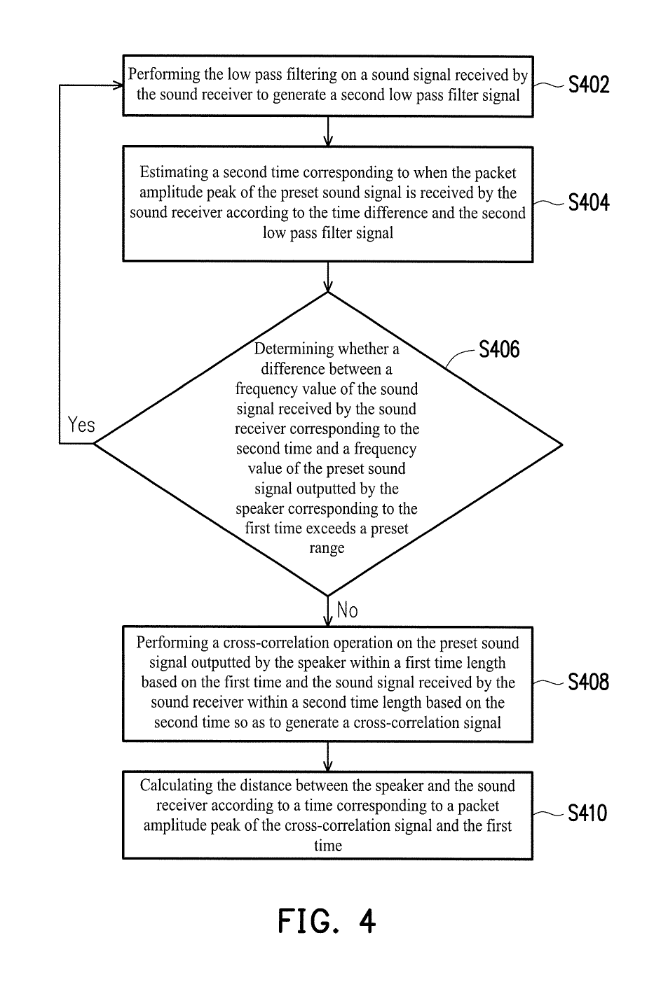

With reference to FIG. 4, FIG. 4 is a flowchart of a distance detection method of a distance detection device according to an embodiment of the invention. In the present embodiment, the distance detection device includes a speaker and a sound receiver. The preset sound signal outputted by the speaker has an amplitude and a frequency that vary over time. A time difference exists between the preset sound signal and a first low pass filter signal obtained after performing a low pass filtering on the preset sound signal. A packet amplitude peak of the preset sound signal is outputted by the speaker at a first time. The low pass filtering may be, for example, an infinite impulse response filtering, but not limited thereto. In view of the foregoing embodiments, it can be known that the distance detection method of the distance detection device may at least include the following steps. First of all, the low pass filtering is performed on a sound signal received by the sound receiver to generate a second low pass filter signal (step S402). Next, a second time corresponding to when the packet amplitude peak of the preset sound signal is received by the sound receiver is estimated according to the time difference and the second low pass filter signal (step S404). The time difference may be, for example, a difference between the first time and a third time corresponding to a packet amplitude peak of the first low pass filter signal. Then, whether a difference between a frequency value of the sound signal received by the sound receiver corresponding to the second time and a frequency value of the preset sound signal outputted by the speaker corresponding to the first time exceeds a preset range is determined (step S406). For instance, the above can be done by performing a Fourier transform operation on the sound signal received by the sound receiver within a first time length based on the second time (e.g., centered on the second time but not limited thereto) so as to obtain the frequency value of the sound signal received by the sound receiver corresponding to the second time, and determining whether a difference between a frequency value of a frequency domain signal having a maximum amplitude in a frequency domain of the sound signal received by the sound receiver within the first time length based on the second time and the frequency value of the preset sound signal outputted by the speaker corresponding to the first time exceeds the preset range. If the difference between the frequency value of the sound signal received by the sound receiver corresponding to the second time and the frequency value of the preset sound signal outputted by the speaker corresponding to the first time does not exceed the preset range, a cross-correlation operation is performed on the preset sound signal outputted by the speaker within a first time length based on the first time and the sound signal received by the sound receiver within a second time length based on the second time so as to generate a cross-correlation signal (step S408). The second time length is greater than the first time length, and the second time length is less than a time required to transmit the preset sound signal for a farthest relative distance possibly disposed between the speaker and the sound receiver within the space. In some embodiments, it is assumed that the preset sound signal has a third time length. In that case, the second time length may be, for example, set to be greater than or equal to the third time length but less than the time required to transmit the preset sound signal for the farthest relative distance possibly disposed between the speaker and the sound receiver within the space. Alternatively, the second time length may also be set to be less than the third time length. For example, the second time length may be set as a time length during which the packet amplitude of the preset sound signal is less than another preset value. Subsequently, the distance between the speaker and the sound receiver is calculated according to a time corresponding to a packet amplitude peak of the cross-correlation signal and the first time (step S410). The cross-correlation operation may be, for example, a fast cross-correlation operation, but not limited thereto.

It should be noted that, according to the distance detection method of the above embodiment, in the case where the distance R1 between the speaker 102 and the sound receiver 104 is fixed, the relative distance R1 between the speaker 102 and the sound receiver 104 may be accurately detected while significantly and effectively saving computational resources. However, in the case where the distance R1 of the speaker 102 and the sound receiver 104 is not fixed, i.e., if the relative velocity between the speaker 102 and the sound receiver 104 is not zero, an accuracy of the detected distance R1 will be reduced. The processor 106 can receive data from the speaker 102 and the sound receiver 104 (e.g., sensed data from a velocity sensor, an acceleration sensor, a gyroscope sensor, a height sensor, a direction on the speaker 102 and the sound receiver 104) through networks or other methods in wired or wireless manner, so as to learn whether or not the relative velocity between the speaker 102 and the sound receiver 104 is zero. When the relative velocity between the speaker 102 and the sound receiver 104 is zero, the processor can detect the distance R1 between the speaker 102 and the sound receiver 104 according to the method described in the foregoing embodiments. When the relative velocity between the speaker 102 and the sound receiver 104 is not zero, the processor can detect the distance R1 between the speaker 102 and the sound receiver 104 by the following method.

The speaker 102 can, for example, output one preset sound signal per one time period, and the preset sound signal s(t) may be expressed by the following equation:

s(t)=A(t)·cos [2π·f(t)·t] (1)

In this equation, t is the time, A(t) is the amplitude of the preset sound signal s(t), and f(t) is the frequency of the preset sound signal s(t). A time length of each time period may be, for example, set as a time length of the preset sound signal s(t) plus the time required to transmit the preset sound signal s(t) for the farthest relative distance possibly disposed between the speaker 102 and the sound receiver 104 within the space.

By doing so, it can be ensured that the sound receiver 104 is able to receive the preset sound signal s(t) sent by the speaker 102 in each time period.

It is assumed that the speaker 121 outputs the preset sound signal s(t) in an m^{th} time period where m is an integer greater than 1, and the packet amplitude peak of the preset sound signal s(t) corresponds to the time t_Tx and a frequency f_TMax. In addition, the sound signal y(t) received by the sound receiver 104 corresponds to the frequency f_RMax at the time t_Max. A frequency f_RMax may be obtained by, for example, performing the Fourier transform operation on the sound signal y(t) received by the sound receiver 104 within the time length T_C based one the time t_Max (e.g., centered on the time t_Max, but not limited thereto) by the processor 106. The frequency f_RMax may be, for example, the frequency value of the frequency domain signal having the maximum amplitude in the frequency domain of the sound signal y(t), but not limited thereto. In some embodiment, the processor 106 can further perform an interpolation operation (e.g., a polynomial interpolation operation, but not limited thereto) on a plurality of frequency domain signals obtained after the Fourier transform operation is performed so as to obtain the frequency f_RMax more accurately. The time length T_C may be, for example, set as a time length during which a packet amplitude of the preset sound signal s(t) is less than a preset value. In other words, only a portion of the preset sound signal s(t) with larger amplitude is used to conduct comparison between the frequency values so an accuracy for calculating the frequency may be improved. Moreover, an amount of operations may also be reduced for the processor 106.

The processor 106 can correct the frequency value of the preset sound signal s(t) by using a Doppler effect according to the relative velocity between the speaker 102 and the sound receiver 104 previously calculated. For instance, the processor 106 can correct the frequency f(t) of the preset sound signal s(t) by using the following equation:

$${f}^{′} ( t ) = f ( t ) \cdot ( 1 + \frac{{v}_{m}^{k - 1}}{c} ) \qquad ( 2 )$$

In this equation, f′(t) is a corrected frequency, vₘ^{k-1} is an initial relative velocity between the speaker 102 and the sound receiver 104 at a (k-1)^{th} stage in the m^{th} time period, c is an acoustical velocity, and k is a positive integer. The corrected preset sound signal x(t) may be expressed by the following equation:

$$x ( t ) = A ( t ) \cdot cos [ 2 π \cdot f ( t ) \cdot ( 1 + \frac{{v}_{m}^{k - 1}}{c} ) \cdot t ] \qquad ( 3 )$$

The initial relative velocity between the speaker 102 and the sound receiver 104 (the relative velocity when k is equal to 1) may be calculated by the processor 106 according to the frequency f_RMax and the frequency f_TMax by, for example, using the following equation:

$${v}_{m}^{0} = c \cdot ( \frac{f\_RMax}{f\_TMax} - 1 ) \qquad ( 4 )$$

In this equation, vₘ⁰ is the initial relative velocity between the speaker 102 and the sound receiver 104 in the m^{th} time period. The processor 106 can perform a cross-correlation operation on the corrected preset sound signal x(t) and the sound signal y(t) received by the sound receiver 104 so as to generate a cross-correlation signal. The cross-correlation operation may be, for example, a fast cross-correlation operation, but not limited thereto. The processor 106 can calculate the distance R1 between the speaker 102 and the sound receiver 104 according to a time corresponding to a packet amplitude peak of the cross-correlation signal and the time t_Tx corresponding to the packet amplitude peak of the preset sound signal s(t).

For instance, a corrected relative distance Rₘ^{k} may be expressed by the following equation:

Rₘ^{k}=(t_Rx−t_Tx)·c (5)

The processor 106 can calculate the relative velocity between the speaker 102 and the sound receiver 104 corresponding to the m^{th} time period according to the corrected relative distance between the speaker 102 and the sound receiver 104 corresponding to the m^{th} time period and the corrected relative distance between the speaker 102 and the sound receiver 104 corresponding to an (m-1)^{th} time period. For instance, the relative velocity vₘ^{k} at a k^{th} stage in the m^{th} time period may be expressed by the following equation:

vₘ^{k}=(Rₘ^{k}−Rₘ₋₁)/Td (6)

In this equation, Td is a time length of each time period, and Rₘ₋₁ is the relative distance calculated for the (m-1)^{th} time period. After obtaining the initial relative velocity vₘ⁰ the processor 106 can start to recursively calculate the relative velocity between the speaker 102 and the sound receiver 104 according to the above equations (2), (3), (5) and (6) until the relative velocity is converged to a specific value. For instance, the processor 106 can determine whether the relative velocity between the speaker 102 and the sound receiver 104 corresponding to the m^{th} time period is converged to fall within a preset range according to the relative velocity between the speaker 102 and the sound receiver 104 corresponding to the m^{th} time period and the relative velocity between the speaker 102 and the sound receiver 104 corresponding to the (m-1)^{th} time period. For example, the processor 106 can determine whether the relative velocity is converged according to the following equation:

$$\vert \frac{{v}_{m}^{k} - {v}_{m}^{k - 1}}{{v}_{m}^{k}} \vert \leq THV \qquad ( 7 )$$

In this equation, THV is a preset threshold. When an absolute value of (vₘ^{k}−vₘ^{k-1})/vₘ^{k} is converged to fall within the preset range from −THV to THV, it means that the accuracy of the corrected relative distance Rₘ^{k} at the k^{th} stage in the m^{th} time period calculated by the processor 106 meets the requirement, and such corrected relative distance may then be used a final confirmed relative distance for the m^{th} time period. Similarly, the relative velocity vₘ^{k} at the k^{th} stage in the m^{th} time period may also be used as a final confirmed relative velocity for the m^{th} time period. In addition, a final continued relative acceleration aₘ between the speaker 102 and the sound receiver 104 may be expressed by the following equation:

aₘ=(vₘ−vₘ₋₁)/Td (8)

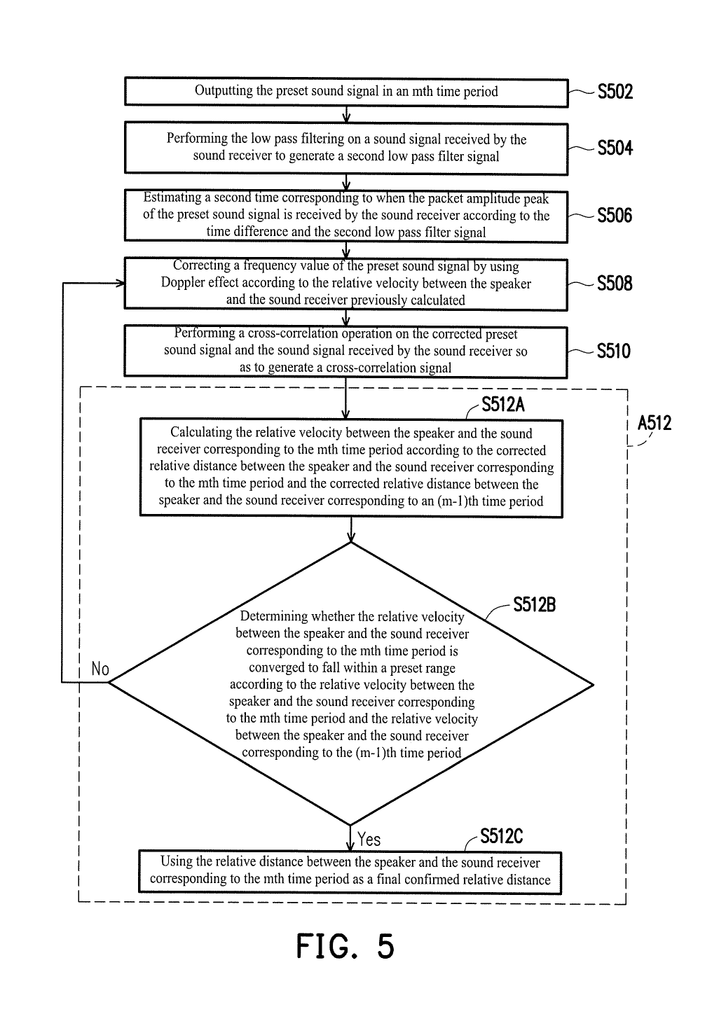

With reference to FIG. 5, FIG. 5 is a flowchart of a distance detection method of a distance detection device according to an embodiment of the invention. In the present embodiment, the distance detection device includes a speaker and a sound receiver. The preset sound signal outputted by the speaker has an amplitude and a frequency that vary over time. A time difference exists between the preset sound signal and a first low pass filter signal obtained after performing a low pass filtering on the preset sound signal. A packet amplitude peak of the preset sound signal is outputted by the speaker at a first time. The preset sound signal outputted by the speaker has a first frequency at the first time. The low pass filtering may be, for example, an infinite impulse response filtering, but not limited thereto. In view of the foregoing embodiments, when the relative velocity between the speaker 102 and the sound receiver 104 is not zero, the distance detection method of the distance detection device may at least include the following steps. First, the preset sound signal is outputted in an m^{th} time period (step S502) where m is an integer greater than 1. Further, a time length of each time period for outputting the preset sound signal may be, for example, equal to a time length required to transmit the preset sound signal for a farthest relative distance possibly disposed between the speaker and the sound receiver within the space.

Next, the low pass filtering is performed on a sound signal received by the sound receiver to generate a second low pass filter signal (step S504). Then, a second time corresponding to when the packet amplitude peak of the preset sound signal is received by the sound receiver is estimated according to the time difference and the second low pass filter signal (step S506). The sound signal received by the sound receiver at the second time corresponds to a second frequency. The second frequency may be obtained by, for example, performing a Fourier transform operation on the sound signal received by the sound receiver within a time length centered on the second time. In some embodiment, an interpolation operation may be further performed on a plurality of frequency domain signals obtained after the Fourier transform operation is performed so as to obtain the second frequency. In addition, the time difference may be, for example, a difference between the first time and a third time corresponding to a packet amplitude peak of the first low pass filter signal. Subsequently, a frequency value of the preset sound signal is corrected by using a Doppler effect according to the relative velocity between the speaker and the sound receiver previously calculated (step S508). Then, a cross-correlation operation is performed on the corrected preset sound signal and the sound signal received by the sound receiver so as to generate a cross-correlation signal (step S510). The cross-correlation operation may be, for example, a fast cross-correlation operation, but not limited thereto. Next, the distance between the speaker and the sound receiver is calculated according to a time corresponding to a packet amplitude peak of the cross-correlations signal so as to obtain a corrected relative distance (step S512).

For instance, in step S512, the relative velocity between the speaker and the sound receiver corresponding to the m^{th} time period may first be corrected according to the corrected relative distance between the speaker and the sound receiver corresponding to the m^{th} time period and the corrected relative distance between the speaker and the sound receiver corresponding to an (m-1)^{th} time period (step S512A). The initial relative velocity between the speaker and the sound receiver may be calculated by using the Doppler effect according to the first frequency and the second frequency. Then, whether the relative velocity between the speaker and the sound receiver corresponding to the m^{th} time period is converged to fall within a preset range is determined according to the relative velocity between the speaker and the sound receiver corresponding to the m^{th} time period and the relative velocity between the speaker and the sound receiver corresponding to the (m-1)^{th} time period (step S512B). If the relative velocity is converged to fall within the preset range, the relative velocity between speaker and the sound receiver corresponding to the m^{th} time period is used as a final relative distance (step S512C). Conversely, if the relative velocity is not converged to fall within the preset range, the process may go back to step S508, in which the frequency value of the preset sound signal is adjusted again according to the newly calculated relative velocity, and then proceed to the subsequent steps for calculating the relative distance until a result that can be used as the final confirmed relative distance is obtained.

In summary, based on the embodiments of the invention, the second time when the packet amplitude peak of the preset sound signal is received by the sound receiver is estimated according to the time difference between the preset sound signal and the low pass filter signal thereof and the low pass filter signal of the sound signal received by the sound receiver. When the frequency value of the sound signal received by the sound receiver at the second time is approximate to the frequency of the packet amplitude peak of the preset sound signal outputted at the first time, the cross-correlation operation is performed on the preset sound signal outputted by the speaker within the first time length based on the first time and the sound signal received by the sound receiver within the second time length based on the second time so as to generate the cross-correlation signal, and the distance between the speaker and the sound receiver is calculated according to the time corresponding to the packet amplitude peak of the cross-correlation signal and the first time. The second time length is greater than the first time length. As a result, simply by performing the cross-correlation operation on the preset sound signal outputted by the speaker within the first time length based on the first time and the sound signal received by the sound receiver within the second time length based on the second time, the relative distance between the speaker and the sound receiver may be accurately calculated while significantly and effectively saving computational resources.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A distance detection device, comprising:
a speaker, outputting a preset sound signal, the preset sound signal having an amplitude and a frequency that vary over time, a time difference existing between the preset sound signal and a first low pass filter signal obtained after performing a low pass filtering on the preset sound signal, a packet amplitude peak of the preset sound signal being outputted by the speaker at a first time;
a sound receiver; and
a processor, performing the low pass filtering on a sound signal received by the sound receiver to generate a second low pass filter signal, the processor estimating a second time corresponding to when the packet amplitude peak of the preset sound signal is received by the sound receiver according to the time difference and the second low pass filter signal, the processor calculating a distance between the speaker and the sound receiver according to the second time.

2. The distance detection device according to claim 1, wherein the processor further determines whether a relative velocity between the speaker and the sound receiver is zero, when the relative velocity between the speaker and the sound receiver is zero and a difference between a frequency value of the sound signal received by the sound receiver corresponding to the second time and a frequency value of the preset sound signal outputted by the speaker corresponding to the first time does not exceed a preset range, the processor performs a cross-correlation operation on the preset sound signal outputted by the speaker within a first time length based on the first time and the sound signal received by the sound receiver within a second time length based on the second time so as to generate a cross-correlation signal, and calculates the distance between the speaker and the sound receiver according to a time corresponding to a packet amplitude peak of the cross-correlation signal and the first time, wherein the second time length is greater than the first time length.

3. The distance detection device according to claim 2, wherein the processor performs a Fourier transform operation on the sound signal received by the sound receiver within the first time length based on the second time and determines whether a difference between a frequency value of the sound signal received by the sound receiver having a maximum amplitude in a frequency domain within the first time length based on the second time and the frequency value of the preset sound signal outputted by the speaker corresponding to the first time exceeds the preset range, and when the preset range is not exceeded, the processor performs the cross-correlation operation on the preset sound signal outputted by the speaker within the first time length based on the first time and the sound signal received by the sound receiver within the second time length based on the second time.

4. The distance detection device according to claim 2, wherein the time difference is a difference between the first time and a third time corresponding to a packet amplitude peak of the first low pass filter signal.

5. The distance detection device according to claim 2, wherein the speaker and the sound receiver are disposed in a space, and the second time length is less than a time length required to transmit the preset sound signal for a farthest relative distance possibly disposed between the speaker and the sound receiver within the space,
wherein the preset sound signal has a third time length, and the second time length is greater than or equal to the third time length.

6. The distance detection device according to claim 1, wherein the speaker outputs the preset sound signal in an m^{th} time period where m is an integer greater than 1, the preset sound signal has a first frequency at the first time, the processor further determines whether a relative velocity between the speaker and the sound receiver is zero, when the relative velocity between the speaker and the sound receiver is not zero, the processor corrects a frequency value of the preset sound signal by using a Doppler effect according to the relative velocity between the speaker and the sound receiver previously calculated, performs a cross-correlation operation on the corrected preset sound signal and the sound signal received by the sound receiver so as to generate a cross-correlation signal, and calculates the distance between the speaker and the sound receiver according to a time corresponding to a packet amplitude peak of the cross-correlations signal and the first time so as to obtain a corrected relative distance, wherein a sound signal received by the sound receiver at the second time corresponds to a second frequency.

7. The distance detection device according to claim 6, wherein the processor calculates the relative velocity between the speaker and the sound receiver corresponding to the m^{th} time period according to the corrected relative distance between the speaker and the sound receiver corresponding to the m^{th} time period and the corrected relative distance between the speaker and the sound receiver corresponding to an (m-1)^{th} time period, and determines whether the relative velocity between the speaker and the sound receiver corresponding to the m^{th} time period is converged to fall within a preset range according to the relative velocity between the speaker and the sound receiver corresponding to the m^{th} time period and the relative velocity between the speaker and the sound receiver corresponding to the (m-1)^{th} time period.

8. The distance detection device according to claim 7, wherein the relative distance between the speaker and the sound receiver corresponding to the m^{th} time period is used as a final confirmed relative distance when a difference between the relative velocity between the speaker and the sound receiver corresponding to the m^{th} time period and the relative velocity between the speaker and the sound receiver corresponding to the (m-1)^{th} time period divided by the relative velocity between the speaker and the sound receiver corresponding to the m^{th} time period does not exceed the preset range.

9. The distance detection device according to claim 6, wherein the processor calculates an initial relative velocity between the speaker and the sound receiver by using the Doppler effect according to the first frequency and the second frequency.

10. The distance detection device according to claim 6, wherein the processor performs a Fourier transform operation on the sound signal received by the sound receiver within a time length centered on the second time so as to obtain the second frequency,
wherein the processor further performs an interpolation operation on a plurality of frequency domain signals obtained after the Fourier transform operation is performed so as to obtain the second frequency.

11. The distance detection device according to claim 6, wherein the time difference is a difference between the first time and a third time corresponding to a packet amplitude peak of the first low pass filter signal.

12. A distance detection method of a distance detection device, the distance detection device comprising a speaker and a sound receiver, the speaker outputting a preset sound signal, the preset sound signal having an amplitude and a frequency that vary over time, a time difference existing between the preset sound signal and a first low pass filter signal obtained after performing a low pass filtering on the preset sound signal, a packet amplitude peak of the preset sound signal being outputted by the speaker at a first time, the distance detection method of the distance detection device comprising:
performing the low pass filtering on a sound signal received by the sound receiver to generate a second low pass filter signal;
estimating a second time corresponding to when the packet amplitude peak of the preset sound signal is received by the sound receiver according to the time difference and the second low pass filter signal;
calculating a distance between the speaker and the sound receiver according to the second time.

13. The distance detection method of the distance detection device according to claim 12, comprising:
determining whether a relative velocity between the speaker and the sound receiver is zero;
when the relative velocity between the speaker and the sound receiver is zero, determining whether a difference between a frequency value of the sound signal received by the sound receiver corresponding to the second time and a frequency value of the preset sound signal outputted by the speaker corresponding to the first time exceeds a preset range;
if the difference between the frequency value of the sound signal received by the sound receiver corresponding to the second time and the frequency value of the preset sound signal outputted by the speaker corresponding to the first time does not exceed the preset range, performing a cross-correlation operation on the preset sound signal outputted by the speaker within a first time length based on the first time and the sound signal received by the sound receiver within a second time length based on the second time so as to generate a cross-correlation signal, wherein the second time length is greater than the first time length; and
calculating the distance between the speaker and the sound receiver according to a time corresponding to a paket amplitude peak of the cross-correlation signal and the first time.

14. The distance detection method of the distance detection device according to claim 13, comprising:
performing a Fourier transform operation on the sound signal received by the sound receiver within the first time length based on the second time;
determining whether a difference between a frequency value of the sound signal received by the sound receiver having a maximum amplitude in a frequency domain within the first time length based on the second time and the frequency value of the preset sound signal outputted by the speaker corresponding to the first time exceeds the preset range; and
if the preset range is not exceeded, performing the cross-correlation operation on the preset sound signal outputted by the speaker within the first time length based on the first time and the sound signal received by the sound receiver within the second time length based on the second time.

15. The distance detection method of the distance detection device according to claim 13, wherein the first time length is a time length during which a packet amplitude of the preset sound signal is less than a preset value.

16. The distance detection method of the distance detection device according to claim 12, wherein the speaker outputs the preset sound signal in an m^{th} time period where m is an integer greater than 1, the preset sound signal outputted by the speaker has a first frequency at the first time, and the distance detection method of the distance detection device comprises:
determining whether a relative velocity between the speaker and the sound receiver is zero;
when the relative velocity between the speaker and the sound receiver is not zero, estimating the second time corresponding to when the packet amplitude peak of the preset sound signal is received by the sound receiver according to the time difference and the second low pass filter signal, wherein the sound signal received by the sound receiver at the second time corresponds to a second frequency;
correcting a frequency value of the preset sound signal by using a Doppler effect according to the relative velocity between the speaker and the sound receiver previously calculated;
performing a cross-correlation operation on the corrected preset sound signal and the sound signal received by the sound receiver so as to generate a cross-correlation signal; and
calculating the distance between the speaker and the sound receiver according to a time corresponding to a packet amplitude peak of the cross-correlations signal and the first time so as to obtain a corrected relative distance.

17. The distance detection method of the distance detection device according to claim 16, comprising:
calculating the relative velocity between the speaker and the sound receiver corresponding to the m^{th} time period according to the corrected relative distance between the speaker and the sound receiver corresponding to the m^{th} time period and the corrected relative distance between the speaker and the sound receiver corresponding to an (m-1)^{th} time period; and
determining whether the relative velocity between the speaker and the sound receiver corresponding to the m^{th} time period is converged to fall within a preset range according to the relative velocity between the speaker and the sound receiver corresponding to the m^{th} time period and the relative velocity between the speaker and the sound receiver corresponding to the (m-1)^{th} time period.

18. The distance detection method of the distance detection device according to claim 17, wherein using the relative distance between the speaker and the sound receiver corresponding to the m^{th} time period as a final confirmed relative distance when a difference between the relative velocity between the speaker and the sound receiver corresponding to the m^{th} time period and the relative velocity between the speaker and the sound receiver corresponding to the (m-1)^{th} time period divided by the relative velocity between the speaker and the sound receiver corresponding to the m^{th} time period does not exceed the preset range.

19. The distance detection method of the distance detection device according to claim 16, wherein the time difference is a difference between the first time and a third time corresponding to a packet amplitude peak of the first low pass filter signal, wherein the speaker and the sound receiver are disposed within a space, and a time length of each time period for outputting the preset sound signal is equal to a time length required to transmit the preset sound signal for a farthest relative distance possibly disposed between the speaker and the sound receiver within the space,
wherein the low pass filtering is an infinite impulse response filtering,
wherein the cross-correlation operation is a fast cross-correlation operation.
